(19) United States
(12) Patent Application Publication
(10) Pub. No.: US 2002/0041027 A1
(43) Pub. Date: Apr. 11, 2002

(54) Semiconductor device

(75) Inventor: Yoshiaki Sugizaki, Yokohama-shi (JP)

Correspondence Address: Finnegan, Henderson, Farabow, Garrett & Dunner, L.L.P., 1300 I Street, N.W., Washingon, DC, 20005-3315, US

(73) Assignee: KABUSHIKI KAISHA TOSHIBA

(21) Appl. No.: 09/972,855

(22) Filed: Oct. 10, 2001

(30) Foreign Application Priority Data
Oct. 10, 2000 (JP) 2000-309764

(51) Int. Cl. H01L 21/44; H01L 23/48

(52) U.S. Cl. 257/737; 438/613

(57) ABSTRACT

A semiconductor device is disclosed, which comprise a first semiconductor chip where a semiconductor element is formed, a first connecting terminal arranged on a semiconductor element formation surface side in the first semiconductor chip and connected electrically to the semiconductor element, a conductive member buried in a through hole that goes through the first semiconductor chip, a second connecting terminal arranged on a back surface side of the semiconductor element formation surface in the first semiconductor chip, and connected electrically to the semiconductor element via the conductive member, a wiring substrate to which the first semiconductor chip is mounted, and a third connecting terminal at least portion of which is formed at a position corresponding to one of the first connecting terminal and the second connecting terminal, and which is electrically connected to the one of the first connecting terminal and the second connecting terminal.

### CROSS-REFERENCE TO RELATED APPLICATIONS

This application is based upon and claims the benefit of priority from the prior Japanese Patent Application No. 2000-309764, filed Oct. 10, 2000, the entire contents of which are incorporated herein by reference.

### BACKGROUND OF THE INVENTION

1. Field of the Invention

The present invention relates to a semiconductor device of a package structure in which a through hole with a conductive member buried therein is formed in a semiconductor chip, and wirings are derived from a semiconductor element formation surface side and a back surface side thereof, more specifically, the invention relates to a high performance semiconductor device having enhanced power source.

2. Description of the Related Art

With the low voltage tendency in power voltage along with ultra fine structure in semiconductor integrated circuits, and with the increase of semiconductor chip size along with the increased circuit scale, the problem of voltage drop in semiconductor chips has become conspicuous. As for the countermeasures against this problem, a package of a flip chip structure, where connecting terminals are arranged over the entire surface of a semiconductor chip and are connected to a multi layer wiring substrate in face-down manners, has become the main stream.

FIG. 29 is a cross sectional view showing an outline structure of a conventional semiconductor device as mentioned above. In FIG. 29, reference numeral 21 is a semiconductor chip, reference numeral 22 is a semiconductor element formation surface in the semiconductor chip 21, reference numeral 23 is a connecting terminal (conductive bump) arranged on the formation surface 22 of the semiconductor chip 21, while reference numeral 24 is an ultra fine wiring substrate. The semiconductor chip 21 is mounted onto the wiring substrate 24 through the conductive bump 23 so that a formation surface 22 of the semiconductor element (internal circuit) faces to the surface of the wiring substrate 24 at the chip 21 side, namely in face-down status. The ultra fine wiring substrate 24 comprises an insulated substrate main body 24A made of resin, ceramic or the like, and a wiring layer (multi layer wiring) 24B is formed on the surface of the chip 21 side, the back surface and the inside of the wiring substrate 24. The bump 23 is arranged on the surface of the semiconductor element formation surface 22 side of the semiconductor chip 21 corresponding to the wiring layer 24B on the surface of the chip 21 side of the wiring substrate 24, and, the semiconductor element formation surface 22 of the semiconductor chip 21 is electrically connected through the bump 23 to the wiring layer 24B of the ultra fine wiring substrate 24. The wiring layer 24B on the surface of the chip 21 side of the wiring substrate 24 is also communicated to a wiring layer 24B arranged in the wiring substrate 24 and derived to the back surface side of the wiring substrate 24, and is electrically connected to a connecting terminal (conductive bump) 25 arranged on the back surface of the wiring substrate 24 for connection to a mother board.

However, in order to realize a semiconductor device having the structure mentioned above, many signal lines to be connected to the semiconductor chip 21 must be located in the ultra fine wiring substrate 24, which requires fine patterning, leading to high costs.

While, for high speed signal transmission among a plurality of semiconductor chips, there is also suggested a package having a structure wherein by the semiconductor element formation surfaces of semiconductor chips facing to each other, many connecting terminals are connected in shortest distances.

However, in such a package structure, when it is intended to reinforce power source, since circuit formation surfaces of the respective semiconductor chips face to each other, power source can be supplied only from the external circumference of the chip stacked area, as a result, it has been impossible to solve the problem of voltage drop in a semiconductor chips, which has been a problem with the prior art.

As mentioned above, in the conventional semiconductor devices, the problems of voltage drop in semiconductor chips have become serious issues, nevertheless, if efforts are made so as to solve these problem, it has led to high costs, which has been another problem seen in the prior art.

Further, a semiconductor device of a package structure for high speed signal transmission availability, however, even with such a structure, it has been impossible to solve the problem of voltage drop in semiconductor chips, which has been still another problem with the prior art.

### BRIEF SUMMARY OF THE INVENTION

According to an aspect of the present invention, there is provided a semiconductor device comprising:

a first semiconductor chip where a semiconductor element is formed;

a first connecting terminal arranged on a semiconductor element formation surface side in the first semiconductor chip, and connected electrically to the semiconductor element;

a conductive member buried in a through hole that goes through the first semiconductor chip;

a second connecting terminal arranged on a back surface side of the semiconductor element formation surface in the first semiconductor chip, and connected electrically to the semiconductor element via the conductive member;

a wiring substrate to which the first semiconductor chip is mounted; and

a third connecting terminal at least portion of which is formed at a position corresponding to one of the first connecting terminal and the second connecting terminal, and which is electrically connected to the one of the first connecting terminal and the second connecting terminal.

According to another aspect of the present invention, there is provided a semiconductor device comprising:

a first semiconductor chip where a semiconductor element is formed;

a first connecting terminal arranged on a semiconductor element formation surface side in the first semiconductor chip, and connected electrically to the semiconductor element;

a conductive member buried in a through hole that goes through the first semiconductor chip;

a second connecting terminal arranged on a back surface side of the semiconductor element formation surface in the first semiconductor chip, and connected electrically to the semiconductor element via the conductive member;

a lead frame to which the first semiconductor chip is mounted, and at least part of which is arranged at a position facing to one of the first connecting terminal and the second connecting terminal, and which is electrically connected to the one connecting terminal; and

an insulator that seals an inner lead portion of the lead frame and the first semiconductor chip.

According to a further aspect of the present invention, there is provided a semiconductor device comprising:

a first semiconductor chip where a semiconductor element is formed;

a plurality of first connecting terminals arranged on a semiconductor element formation surface side in the first semiconductor chip, and connected electrically to the semiconductor element;

conductive members buried in a plurality of through holes that go through the first semiconductor chip; and

a plurality of second connecting terminals arranged on a back surface side of the semiconductor element formation surface in the first semiconductor chip, and connected electrically to the semiconductor element via the conductive members;

wherein, at least either the first connecting terminals or the second connecting terminals is coupled to a assembly board.

According to a still further aspect of the present invention, there is provided a semiconductor device comprising:

a first semiconductor chip where a semiconductor element is formed;

a first connecting terminal arranged on a semiconductor element formation surface side in the first semiconductor chip, and connected electrically to the semiconductor element;

a conductive member buried in a through hole that goes through the first semiconductor chip;

a second connecting terminal arranged on a back surface side of the semiconductor element formation surface in the first semiconductor chip, and connected electrically to the semiconductor element via the conductive member;

a second semiconductor chip stacked on the first semiconductor chip;

a third connecting terminal arranged on a semiconductor element formation surface side in the second semiconductor chip;

wherein, one of the first connecting terminal and the second connecting terminal of the first semiconductor chip is arranged at a position facing to the third connecting terminal of the second semiconductor chip, the first semiconductor chip and the second semiconductor chip are electrically connected with each other through the facing connecting terminals, and

the second semiconductor chip is thicker or larger than the first semiconductor chip.

### BRIEF DESCRIPTION OF THE SEVERAL VIEWS OF THE DRAWING

FIGS. 1A and 1B explain a semiconductor device according to a first embodiment of the present invention. FIG. 1A is a cross sectional view showing an outline structure, while FIG. 1B is an enlarged cross sectional view of part of FIG. 1A.

FIGS. 2A and 2B explain a semiconductor device according to a second embodiment of the present invention. FIG. 2A is a cross sectional view showing an outline structure, while FIG. 2B is an enlarged cross sectional view of part of FIG. 2A.

FIG. 3 is an outline cross sectional view for explaining a semiconductor device according to a third embodiment of the present invention.

FIG. 4 is an outline cross sectional view for explaining a semiconductor device according to a fourth embodiment of the present invention.

FIG. 5 is an outline cross sectional view for explaining a semiconductor device according to a fifth embodiment of the present invention.

FIG. 6 is an outline cross sectional view for explaining a semiconductor device according to a sixth embodiment of the present invention.

FIG. 7 is an outline cross sectional view for explaining a semiconductor device according to a seventh embodiment of the present invention.

FIG. 8 is an outline cross sectional view for explaining a semiconductor device according to an eighth embodiment of the present invention.

FIG. 9 is an outline cross sectional view for explaining a semiconductor device according to a ninth embodiment of the present invention.

FIG. 10 is an outline cross sectional view for explaining a semiconductor device according to a tenth embodiment of the present invention.

FIG. 11 is an outline cross sectional view for explaining a semiconductor device according to an eleventh embodiment of the present invention.

FIG. 12 is an outline cross sectional view for explaining a semiconductor device according to a twelfth embodiment of the present invention.

FIG. 13 is an outline cross sectional view for explaining a semiconductor device according to a thirteenth embodiment of the present invention.

FIG. 14 is an outline cross sectional view for explaining a semiconductor device according to a fourteenth embodiment of the present invention.

FIG. 15 is an outline cross sectional view for explaining a semiconductor device according to a fifteenth embodiment of the present invention.

FIG. 16 is an outline cross sectional view for explaining a semiconductor device according to a sixteenth embodiment of the present invention.

FIG. 17 is an outline cross sectional view for explaining a semiconductor device according to a seventeenth embodiment of the present invention.

FIG. 18 is an outline cross sectional view for explaining a semiconductor device according to an eighteenth embodiment of the present invention.

FIG. 19 is an outline cross sectional view for explaining a semiconductor device according to a nineteenth embodiment of the present invention.

FIG. 20 is an outline cross sectional view for explaining a semiconductor device according to a twentieth embodiment of the present invention.

FIG. 21 is an outline cross sectional view for explaining a semiconductor device according to a twenty first embodiment of the present invention.

FIG. 22 is an outline cross sectional view for explaining a semiconductor device according to a twenty second embodiment of the present invention.

FIG. 23 is an outline cross sectional view for explaining a semiconductor device according to a twenty third embodiment of the present invention.

FIG. 24 is an outline cross sectional view for explaining a semiconductor device according to a twenty forth embodiment of the present invention.

FIG. 25 is an outline cross sectional view for explaining a semiconductor device according to a twenty fifth embodiment of the present invention.

FIG. 26 is an outline cross sectional view for explaining a semiconductor device according to a twenty sixth embodiment of the present invention.

FIG. 27 is an outline cross sectional view for explaining a semiconductor device according to a twenty seventh embodiment of the present invention.

FIG. 28 is an outline cross sectional view for explaining a semiconductor device according to a twenty eighth embodiment of the present invention.

FIG. 29 is an outline cross sectional view for explaining a conventional semiconductor device.

### DETAILED DESCRIPTION OF THE INVENTION

Various embodiments of the present invention will be explained in more details with reference to the accompanying drawings below.

[First Embodiment]

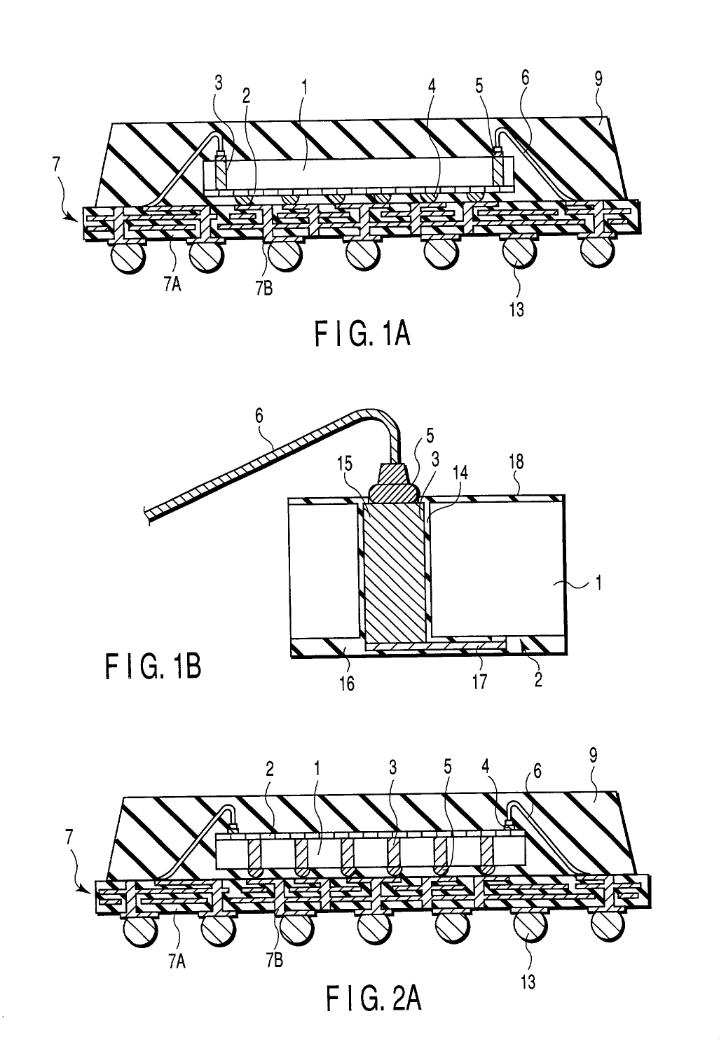

FIGS. 1A and 1B are for explaining a semiconductor device according to a first embodiment of the present invention, respectively. FIG. 1A is a cross sectional view showing an outline structure, while FIG. 1B is an enlarged cross sectional view of part of FIG. 1A.

In FIG. 1A, a semiconductor chip 1 is mounted onto a wiring substrate 7 through a conductive bump 4 so that a formation surface 2 of a semiconductor element (internal circuit) faces to the surface of the chip 1 side of the wiring substrate 7, namely in face-down status. Connecting terminal (conductive bump) 4 being distributed over the entire area (for example, in an array shape) are formed on the formation surface 2 of the semiconductor element. The wiring substrate 7 comprises an insulated substrate main body 7A made of resin or the like, and a wiring layer (multi layer wiring) 7B is formed on the surface of the chip 1 side, the back surface and the inside of the wiring substrate 7. The bump 4 is arranged on the surface of the semiconductor element formation surface 2 side of the semiconductor chip 1 corresponding to the wiring layer 7B on the surface of the chip 1 side of the wiring substrate 7, and the semiconductor element formation surface 2 of the semiconductor chip 1 is electrically connected through the bump 4 to the wiring layer 7B of the wiring substrate 7. The wiring layer 7B on the surface of the chip 1 side of the wiring substrate 7 is also communicated to a wiring layer 7B arranged in the wiring substrate 7 and derived to the back surface side of the wiring substrate 7, and is electrically connected to a connecting terminal (conductive bump) 13 arranged on the back surface of the wiring substrate 7 for connection to a mother board.

On the circumference of the semiconductor chip 1, there is formed a through hole 3 wherein a conductive member is embedded, and on the back surface of the chip, a connecting terminal (pad) 5 is formed onto the conductive member embedded into the through hole 3. The pad 5 and the wiring substrate 7 are connected with each other by a bonding wire 6. The semiconductor chip 1 and the bonding wire 6 on the wiring substrate 7 are sealed by a package 9 made of resin, ceramic or the like.

In the above structure, the parts related to the through hole 3 formed on the semiconductor chip 1 are as shown in FIG. 1B. An insulation film 14 is formed on a side wall of the through hole 3, and an embedded metal (conductive member) 15 in a status insulated from the chip 1 is arranged in this through hole 3. A chip inside wiring 17 made of, for example, copper, aluminum and the like is arranged on the semiconductor element formation surface 2 of the chip 1, and the conductive member 15 is electrically connected to one end of the chip inside wiring 17 on the semiconductor element formation surface 2. The other end of this chip inside wiring 17 is electrically connected to the semiconductor element (internal circuit). The entire surface of the semiconductor element formation surface 2 of the chip 1 including the chip inside wiring 17 is coated with an interlayer insulation film and surface protective film 16. On the other hand, on the back surface of the chip, the pad 5 is arranged on the conductive member 15, and one end of the bonding wire 6 is ball bonded to this pad 5. Further, a back surface insulation film 18 is formed on the back surface of the chip 1 excluding the pad 5 portion.

According to the structure mentioned above, connecting terminals 4 and 5 can be distributed to any of the entire surface facing to the wiring substrate 7 of the semiconductor 1 and the external circumference of the back surface thereof, accordingly, it is possible to increase the number of connecting points without increasing practical connection density.

By allocating the connecting terminal (bump) 4 distributed to the semiconductor element formation surface 2 to a power source system and a ground system, the convenience of the present structure may be made the best of. In general, it is important that connecting terminals of a power source system and a ground system are distributed and arranged on the entire surface of the semiconductor chip 1, and many connecting points are not always required. While, the connection of a signal system requires many contacting points as a matter of course, on the other hand, they are not necessarily to be distributed on the entire surface of the semiconductor chip 1. As a consequence, the power source and the ground system may be routed to the connecting terminal 4 by use of the low cost wiring substrate 7. Further, since many signal terminals are arranged in further expanded to the external circumference by the bonding wire 6 from the circumference of the chip, these signal terminals may also be routed to the connecting terminal 13 on the back side surface by use of the low cost wiring substrate 7.

Therefore, in the semiconductor device according to the above first embodiment, it is possible to realize necessary functions by the minimum costs.

Further, according to the present invention, it is possible to obtain a semiconductor device that can restrict voltage drop in the semiconductor chip inside thereof, even when the semiconductor chip size is enlarged and power source voltage becomes lower. Further, it is possible to obtain a semiconductor device having high performance and yet low cost package structure.

[Second Embodiment]

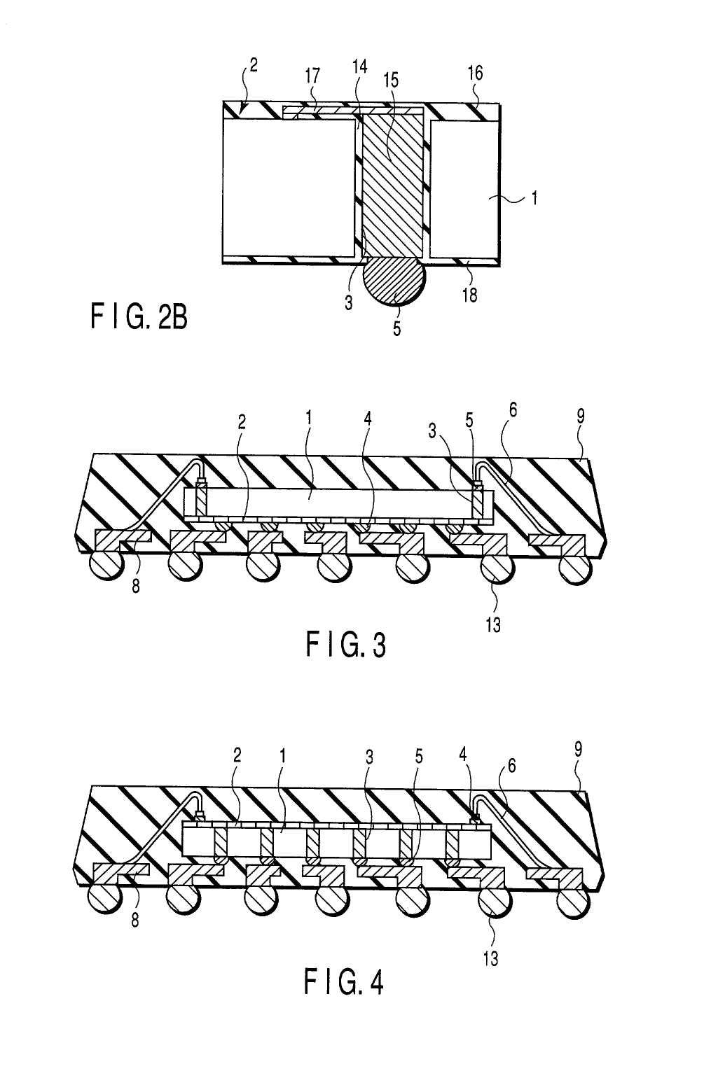

FIGS. 2A and 2B are for explaining a semiconductor device according to a second embodiment of the present invention, respectively. FIG. 2A is a cross sectional view showing an outline structure, while FIG. 2B is an enlarged cross sectional view of part of FIG. 2A. In this second embodiment, a semiconductor chip 1 is mounted onto a wiring substrate 7 through a conductive bump 4 so that the back surface of the semiconductor chip 1 faces to the front surface of the chip 1 side of the wiring substrate 7, namely in face-up status. A through hole 3 wherein a conductive member 15 is buried is distributed and arranged over the entire area of the semiconductor chip 1. On the conductive member 15, there is formed a connecting terminal (conductive bump) 5 on the back surface of the chip 1. Through the conductive member 15 and the bump 5, a semiconductor element formation surface 2 of the semiconductor chip 1 is connected to a wiring layer 7B of the wiring substrate 7. A wiring terminal (pad) 4 is formed on the circumference of the semiconductor element formation surface 2 of the semiconductor chip 1, and this pad 4 is electrically connected to the wiring layer 7B of the wiring substrate 7 by a bonding wire 6.

In the above structure, the parts related to the through hole 3 formed on the semiconductor chip 1 are as shown in FIG. 2B. An insulation film 14 is formed on a side wall of the through hole 3, and an embedded metal (conductive member) 15 in a status insulated from the chip 1 is arranged in this through hole 3. On the semiconductor element formation surface 2 of the chip 1, a chip inside wiring 17 whose one end is electrically connected with the conductive member 15 is arranged. The other end of this chip inside wiring 17 is electrically connected to the semiconductor element (internal circuit). The entire surface of the semiconductor element formation surface 2 of the chip 1 including the chip inside wiring 17 is coated with an interlayer insulation film and surface protective film 16. On the other hand, on the back surface of the chip 1, the bump 5 is arranged on the conductive member 15. The wiring layer 7B of the wiring substrate 7 is connected to this bump 5. Further, the back surface of the chip 1 excluding the bump 5 portion is coated with an insulation film 18.

According to the structure as well as the first embodiment mentioned previously, connecting terminals 4 and 5 can be distributed and arranged to any position proper for connection, it is possible to increase the number of connecting points without increasing practical connection density. In the case of the present structure, it is preferable that a power source system and a ground system are arranged at the connecting terminal (bump) 5 from the same reason mentioned in the above first embodiment.

[Third Embodiment]

FIG. 3 is an outline cross sectional view for explaining a semiconductor device according to a third embodiment of the present invention, and is a modification of the semiconductor device according to the above first embodiment. In this third embodiment, a low cost lead frame 8 is employed in the place of the wiring substrate 7. A bump 4 and a bonding wire 6 are connected to the lead frame 8. Other fundamental structure is same as that of the first embodiment, therefore, identical numerals are placed to same components as those in FIGS. 1A and 1B, and their detailed explanations are omitted here.

In general, in the case of mounting the semiconductor chip 1 onto the lead frame 8, it is not available to form a power source plane or a ground plane as in the case employing the wiring substrate 7. However, in a semiconductor device according to the present embodiment, power source and ground are directly supplied from the portion just below the semiconductor chip 1, as a consequence, it is possible to attain practically sufficient performance.

[Fourth Embodiment]

FIG. 4 is an outline cross sectional view for explaining a semiconductor device according to a fourth embodiment of the present invention, and is a modification of the semiconductor device according to the above second embodiment. In this fourth embodiment, a low cost lead frame 8 is employed in the place of the wiring substrate 7. A bump 5 and a bonding wire 6 are connected to the lead frame 8. Other fundamental structure is same as that of the second embodiment, therefore, identical numerals are placed to same components as those in FIGS. 2A and 2B, and their detailed explanations are omitted here.

In general, in the case of mounting the semiconductor chip 1 onto the lead frame 8, it is not available to form a power source plane or a ground plane as in the case employing the wiring substrate 7. However, as well as in the third embodiment, in the semiconductor device according to the present embodiment, power source and ground are directly supplied from the portion just below the semiconductor chip 1, as a result, it is possible to attain practically sufficient performance.

[Fifth Embodiment]

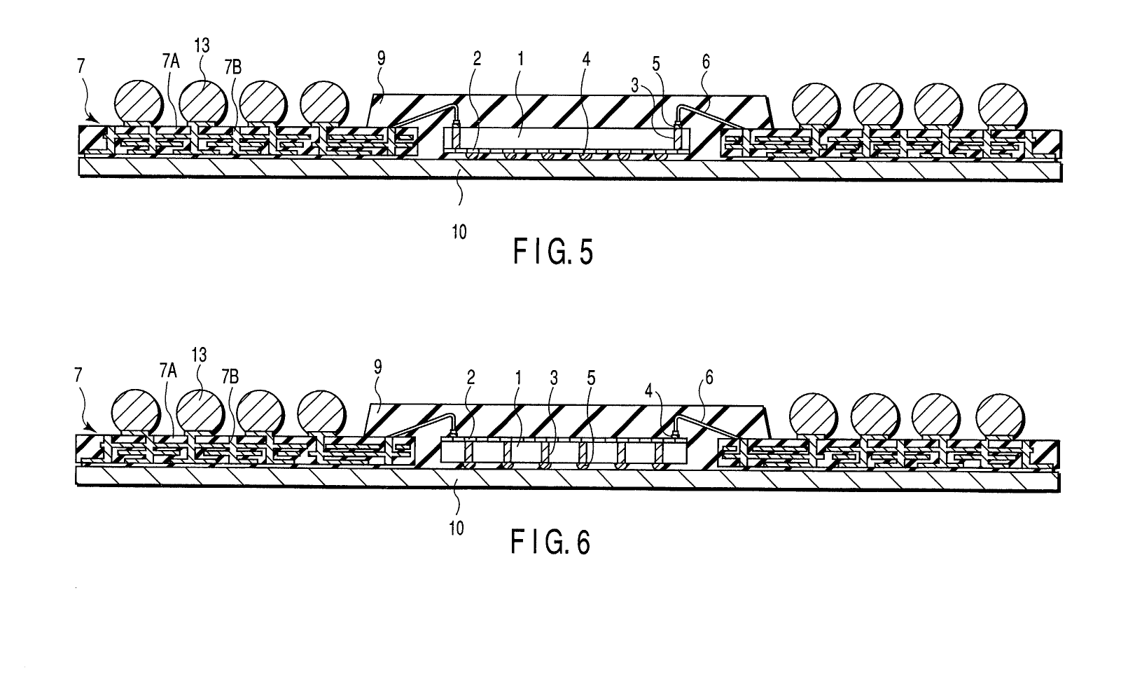

FIG. 5 is an outline cross sectional view for explaining a semiconductor device according to a fifth embodiment of the present invention, and is a modification of the semiconductor device according to the above first embodiment. In this fifth embodiment, a semiconductor chip 1 is mounted onto a heat slug 10, and also a wiring substrate 7 is mounted onto the heat slug 10. The heat slug 10 is a ceramic plate on which a metallic layer or metallic wiring (not illustrated) is formed or a metallic plate, while the metallic layer, the metallic wiring or the metallic plate is connected to a power source system or a ground system.

In the fifth embodiment, the semiconductor chip 1 with a semiconductor element formation surface 2 thereof facing to the heat slug 10 is mounted on the heat slug 10. A connecting terminal (conductive bump) 4 arranged on the semiconductor element formation surface 2 of the semiconductor chip 1 is connected to the metallic wiring layer on the heat slug 10. The wiring substrate 7 is arranged onto the heat slug 10 so as to entangle the semiconductor chip 1. A connecting terminal 13 for board level assembly is arranged on the upper surface of this wiring substrate 7. A connecting terminal (pad) 5 of the semiconductor chip 1 and a wiring 7B of the wiring substrate 7 are electrically connected to each other by a bonding wire 6. The semiconductor chip 1, the bonding wire 6, and the portion in the vicinity of the chip 1 of the wiring substrate 7 are sealed with a package 9 made of resin or the like.

In the structure mentioned above, the connecting terminal (conductive bump) 4 distributed and arranged on the semiconductor element formation surface 2 is allocated to a power source system and a ground system, and through this connecting terminal 4, a conductive path is formed from the element formation surface 2 of the semiconductor chip 1 to the metallic wiring layer on the heat slug 10. The connecting terminal (pad) 5 arranged along the chip circumference on the back surface side of the semiconductor element formation surface 2 is allocated to a signal system. From the element formation surface 2 side of the semiconductor chip 1, through the conductive member 15 in the through hole 3, the connecting terminal 5, the bonding wire 6, and the wiring 7B in the wiring substrate 7 respectively, a conductive path is formed to the connecting terminal 13.

[Sixth Embodiment]

FIG. 6 is an outline cross sectional view for explaining a semiconductor device according to a sixth embodiment of the present invention, and is a modification of the semiconductor device according to the above second embodiment. In this sixth embodiment, a semiconductor chip 1 is mounted onto a heat slug 10, and also a wiring substrate 7 is mounted onto the heat slug 10. The heat slug 10 is a ceramic plate on which a metallic layer or metallic wiring (not illustrated herein) is formed or a metallic plate, while the metallic layer, the metallic wiring or the metallic plate is connected to a power source system or a ground system.

In this sixth embodiment, the semiconductor chip 1 with the back surface thereof (namely, the back surface of the semiconductor chip 1 opposite to the semiconductor element formation surface 2) facing to the heat slug 10 is mounted on the heat slug 10.

A connecting terminal (conductive bump) 5 arranged on the back surface of the semiconductor chip 1 is connected to the metallic wiring layer on the heat slug 10. Further, a wiring substrate 7 is arranged on the heat slug 10 so as to entangle the semiconductor chip 1. A connecting terminal 13 for board level assembly is arranged on the upper surface of this wiring substrate 7. The connecting terminal (pad) 4 of the semiconductor chip 1 arranged on the semiconductor element formation surface 2 and the wiring 7B of the wiring substrate 7 are electrically connected to each other by the bonding wire 6. The semiconductor chip 1, the bonding wire 6, and the portion in the vicinity of the chip 1 of the wiring substrate 7 are sealed with a package 9 made of resin or the like.

In the structure mentioned above, the connecting terminal 5 distributed and arranged on the back surface of the semiconductor chip 1 is allocated to a power source system and a ground system, and through this connecting terminal (bump) 5, a conductive path is formed from the element formation surface 2 side of the semiconductor chip 1 to the metallic wiring layer of the heat slug 10. The connecting terminal 4 arranged along the chip circumference on the semiconductor element formation surface 2 is allocated to a signal system, and through this connecting terminal (pad) 4, the bonding wire 6, and the wiring 7B in the wiring substrate 7, respectively, a conductive path is formed to the connecting terminal 13.

[Seventh Embodiment]

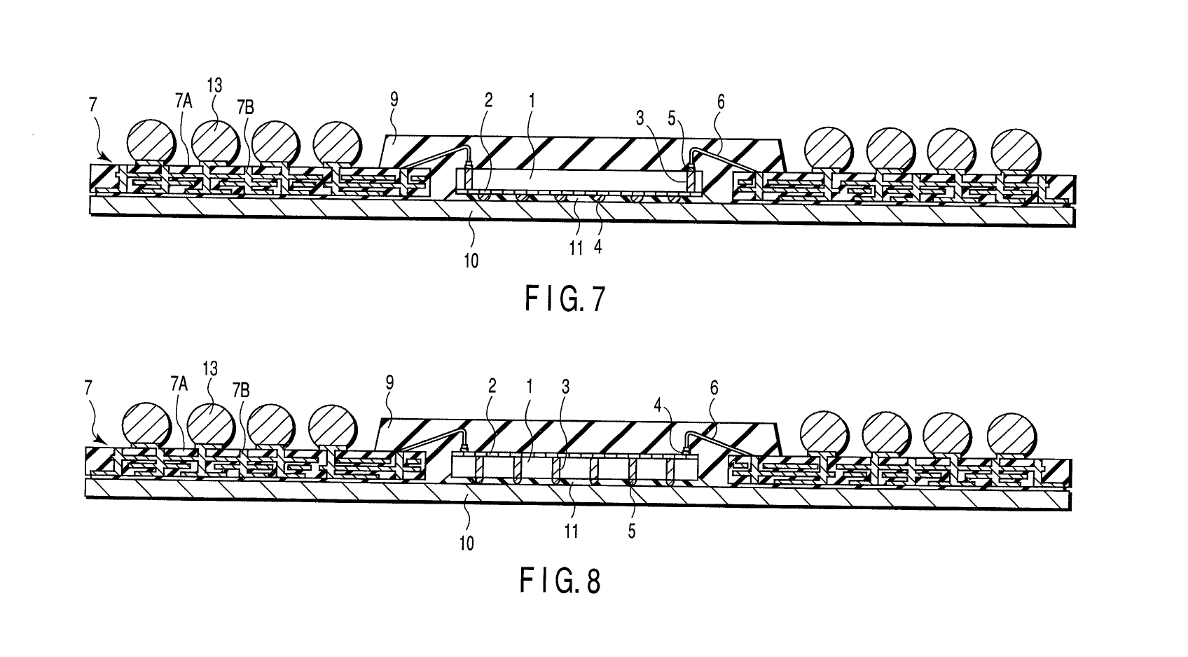

FIG. 7 is an outline cross sectional view for explaining a semiconductor device according to a seventh embodiment of the present invention, and is a modification of the semiconductor device according to the above fifth embodiment. In this seventh embodiment, a highly radiating resin layer 11 (resin layer is generally insulated, and so in this embodiment) is interposed between a heat slug 10 and a semiconductor chip 1 in FIG. 5.

In the seventh embodiment, a connecting terminal 4 arranged on a semiconductor element formation surface 2 of the semiconductor chip 1 is connected to the metallic wiring layer on the heat slug 10, and the highly radiating resin layer 11 is embedded in between the semiconductor chip 1 and the heat slug 10.

By the structure mentioned above, it is possible to increase heat radiation far more than the semiconductor device according to the fifth embodiment.

Meanwhile, in FIG. 7, a general resin layer, i.e., an insulated resin layer is employed as the highly radiating resin layer 11 so as to fill up the space between the insulated semiconductor chip 1 and the heat slug 10, therefore, the connecting terminals 4 are insulated with each other. When using the connecting terminal 4 for either a power source system or a ground system, a highly conductive resin may be employed as the highly radiating resin layer 11, and the connecting terminals 4 may be made conductive with each other.

[Eighth Embodiment]

FIG. 8 is an outline cross sectional view for explaining a semiconductor device according to an eighth embodiment of the present invention, and is a modification of the semiconductor device according to the above sixth embodiment. In this eighth embodiment, a highly radiating resin layer 11 (resin layer is generally insulated, and so in this embodiment) is interposed between a heat slug 10 and a semiconductor chip 1 in FIG. 6.

In the eighth embodiment, a connecting terminal 5 arranged on the back surface of the semiconductor chip 1 is connected to the metallic wiring layer on the heat slug 10, and the highly radiating resin layer 11 is embedded in between the semiconductor chip 1 and the heat slug 10.

By the structure mentioned above, it is possible to increase heat radiation far more than the semiconductor device according to the sixth embodiment.

By the way, in FIG. 8, a general resin layer, i.e., an insulated resin layer is employed as the highly radiating resin layer 11 so as to fill up the space between the insulated semiconductor chip 1 and the heat slug 10, therefore, the connecting terminals 5 are insulated with each other. When using the connecting terminal 5 for either a power source system or a ground system, a highly conductive resin may be employed as the highly radiating resin layer 11, and the connecting terminals 5 may be made conductive with each other.

[Ninth Embodiment]

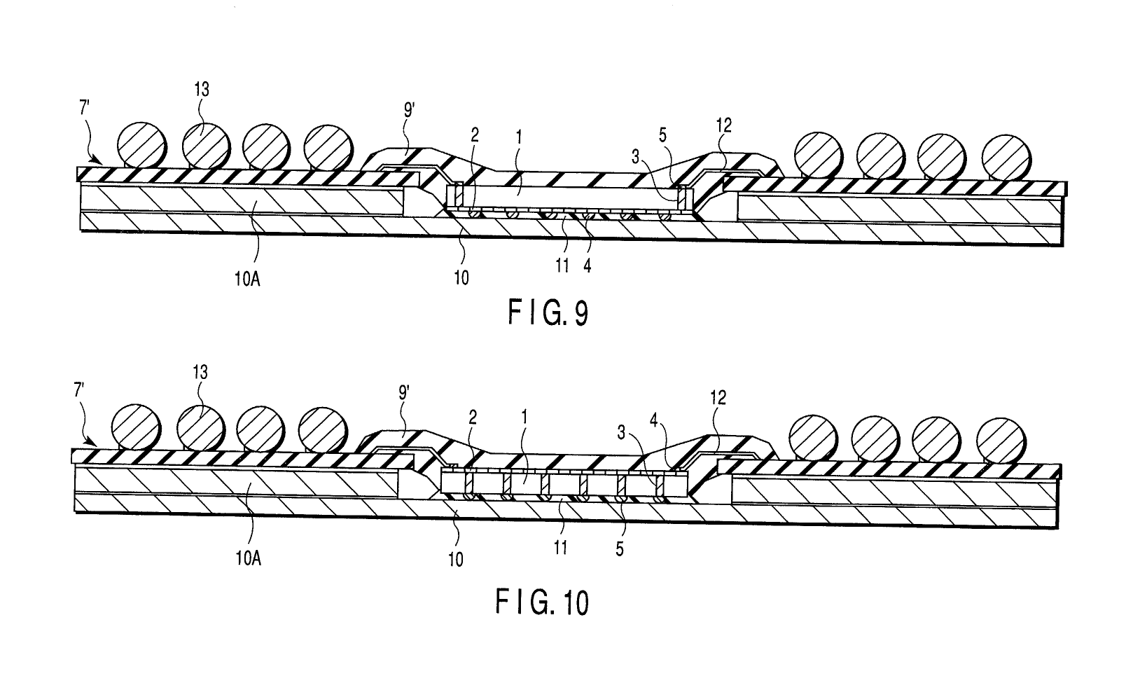

FIG. 9 is an outline cross sectional view for explaining a semiconductor device according to a ninth embodiment of the present invention, and is a modification of the semiconductor device according to the above seventh embodiment. In this ninth embodiment, TAB technology is employed in the place of wiring bonding technology.

In concrete, in the ninth embodiment, onto the heat slug 10, a semiconductor chip 1 is mounted with a semiconductor element formation surface 2 facing to the heat slug 10. A connecting terminal 4 arranged on the semiconductor element formation surface 2 of the semiconductor chip 1 is connected to a metallic wiring layer (not illustrated) on the heat slug 10. A highly radiating resin layer 11 is embedded in between the semiconductor element formation surface 2 of the semiconductor chip 1 and the heat slug 10. The semiconductor chip 1 is arranged in a device hole of a TAB tape 7′, and the TAB tape 7′ is fixed onto a stiffener 10A arranged so as to entangle the semiconductor chip 1. A connecting terminal 13 for board level assembly is arranged to a wiring formed on the upper surface of this TAB tape 7′. A beam lead 12 arranged on the TAB tape 7′ is connected to a connecting terminal 5 of the semiconductor chip 1. The above semiconductor chip 1, the beam lead 12, and the portion in the vicinity of the chip 1 of the above TAB tape 7′ are sealed with a package 9′ that is formed by dropping, for example, potting resin.

In the structure mentioned above, the connecting terminal 4 distributed and arranged on the semiconductor element formation surface 2 is allocated to a power source system and a ground system, and through the connecting terminal 4, a conductive path is formed from the element formation surface 2 of the semiconductor chip 1 to the metallic wiring layer of the above heat slug 10. The connecting terminal 5 on the back surface of the semiconductor chip 1 is allocated to a signal system, and through the conductive member 15, the connecting terminal 5, and the beam lead 12, and the wiring on the upper surface of the TAB tape 7′, respectively, a conductive path is formed from the element formation surface 2 of the semiconductor chip 1 to the above connecting terminal 13.

According to the above ninth embodiment, it is possible to increase heat radiation far more than by the semiconductor according to the fifth embodiment of the present invention, accordingly, the present invention may be applied also to semiconductor devices using the TAB technology.

According to the above ninth embodiment, since the semiconductor chip 1 and the heat slug 10 are connected via the connecting terminal 4, even when using a heat insulating resin as the resin layer 11, it is possible to attain higher heat radiation in comparison with the case where the semiconductor chip 1 and the heat slug 10 are applied directly to each other with heat insulating resin.

By the way, in FIG. 9, a general resin layer, i.e., an insulated resin layer is employed as the highly radiating resin layer 11 so as to fill up the space between the insulated semiconductor chip 1 and the heat slug 10, therefore, the connecting terminals 4 are insulated with each other. When to use the connecting terminal 4 for either a power source system or a ground system, a highly conductive resin may be employed as the highly radiating resin layer 11, and the connecting terminals 4 may be made conductive with each other.

[Tenth Embodiment]

FIG. 10 is an outline cross sectional view for explaining a semiconductor device according to a tenth embodiment of the present invention, and is a modification of the semiconductor device according to the above eighth embodiment. In this tenth embodiment, TAB technology is employed in the place of wiring bonding technology.

In the tenth embodiment, onto the heat slug 10, a semiconductor chip 1 is mounted with the back surface of the semiconductor chip 1 facing to the above heat slug 10. A connecting terminal 5 arranged on the back surface of the above semiconductor chip 1 is connected to the metallic wiring layer on the above heat slug 10. The highly radiating resin layer 11 is embedded in between the back surface of the semiconductor chip 1 and the heat slug 10. The above semiconductor chip 1 is arranged in a device hole of a TAB tape 7′, and the TAB Tape 7′ is fixed onto a stiffener 10A arranged so as to entangle the semiconductor chip 1. A connecting terminal 13 for board level assembly is arranged to a wiring formed on the upper surface of this TAB tape 7′. The beam lead arranged on the above TAB tape 7′ is connected to the connecting terminal 4 arranged on the semiconductor element formation surface 2 of the above semiconductor chip 1. The above semiconductor chip 1, the beam lead 12, and the portion in the vicinity of the chip 1 of the above TAB tape 7′ are sealed with a package 9′ that is formed by dropping, for example, potting resin.

In the structure mentioned above, the connecting terminal 5 distributed and arranged on the back surface of the chip 1 is allocated to a power source system and a ground system, and through the connecting terminal 5, a conductive path is formed from the element formation surface 2 of the semiconductor chip 1 to the metallic wiring layer of the heat slug 10. The connecting terminal 4 on the semiconductor element formation surface 2 is allocated to a signal system, and through the connecting terminal 4, the beam lead 12, and the wiring on the upper surface of the TAB Tape 7′, respectively, a conductive path is formed from the element formation surface 2 to the connecting terminal 13.

According to the above tenth embodiment, it is possible to increase heat radiation far more than by the semiconductor according to the fifth embodiment of the present invention, accordingly, the present invention may be applied also to semiconductor devices using the TAB technology.

According to the above tenth embodiment, since the semiconductor chip 1 and the heat slug 10 are connected via the connecting terminal, even when using a heat insulating resin as the resin layer 11, it is possible to attain higher heat radiation in comparison with the case wherein the semiconductor chip 1 and the heat slug 10 are applied directly to each other with heat insulating resin.

By the way, in FIG. 10, a general resin layer, i.e., an insulated resin layer is employed as the highly radiating resin layer 11 so as to fill up the space between the insulated semiconductor chip 1 and the heat slug 10, therefore, the connecting terminals 5 are insulated with each other. When to use the connecting terminal for either a power source system or a ground system, a highly conductive resin may be employed as the highly radiating resin layer 11, and the connecting terminals 5 may be made conductive with each other.

[Eleventh Embodiment]

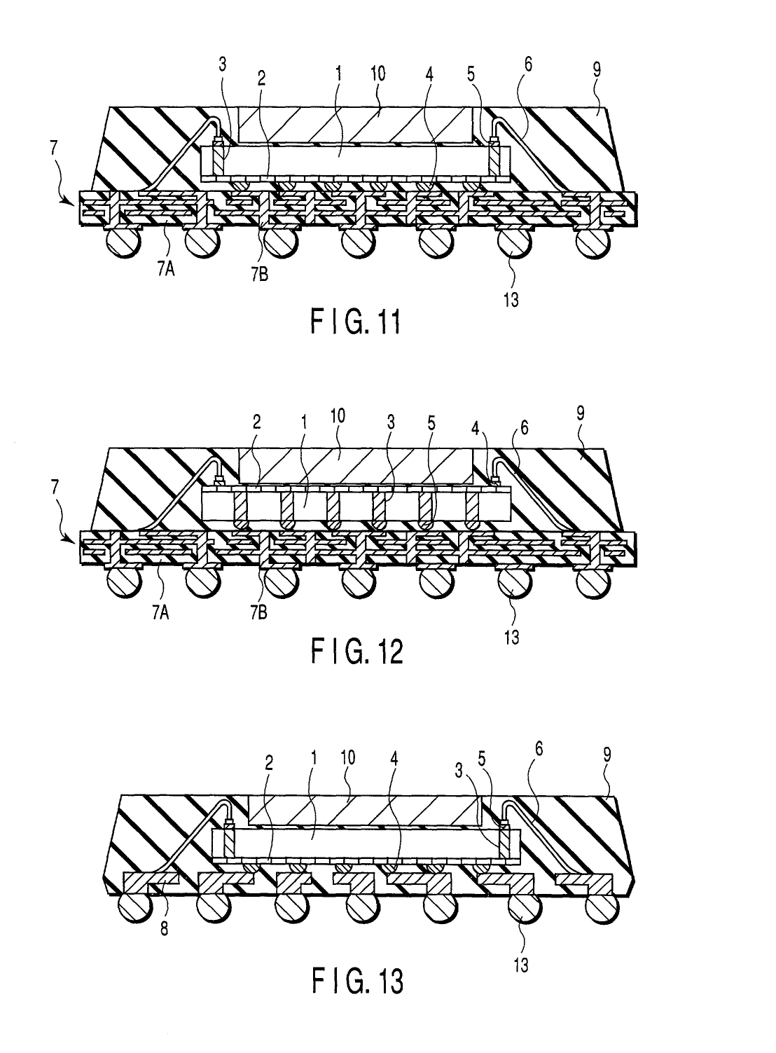

FIG. 11 is an outline cross sectional view for explaining a semiconductor device according to a eleventh embodiment of the present invention, and is a modification of the semiconductor device according to the above first embodiment. In this eleventh embodiment, a heat radiating plate is arranged on a semiconductor chip 1 of a package 9. A heat slug 10 is employed as the heat radiating plate, and the surface of this heat slug 10 is not coated with resin but exposed.

By the way, in the present embodiment, the heat slug 10 is used only for heat radiation, therefore there is no need to apply electric potential. Accordingly, it should not always be a conductive material, but a pure ceramic not having a wiring layer may be employed. As a matter of course, a metal may be employed too.

According to the structure mentioned above, it is possible to further increase heat radiating effects, and the present embodiment may be employed preferably to the semiconductor chip 1 where much heat is generated.

[Twelfth Embodiment]

FIG. 12 is an outline cross sectional view for explaining a semiconductor device according to a twelfth embodiment of the present invention, and is a modification of the semiconductor device according to the above second embodiment. In this twelfth embodiment, a heat radiating plate is arranged on a semiconductor chip 1 of a package 9. A heat slug 10 is employed as the heat radiating plate, and the surface of this heat slug 10 is not coated with resin but exposed.

By the way, in the present embodiment, the heat slug 10 is used only for heat radiation, therefore there is no need to apply electric potential. Accordingly, it should not always be a conductive material, but a pure ceramic not having a wiring layer may be employed. As a matter of course, a metal may be employed too.

According to the structure mentioned above, it is possible to further increase heat radiating effects, and the present embodiment may be employed preferably to the semiconductor chip 1 having large heat generating amount.

[Thirteenth Embodiment]

FIG. 13 is an outline cross sectional view for explaining a semiconductor device according to a thirteenth embodiment of the present invention, and is a modification of the semiconductor device according to the above third embodiment. In this thirteenth embodiment, as same in the above eleventh embodiment, a heat radiating plate is arranged on a semiconductor chip 1 of a package 9. A heat slug 10 is employed as the heat radiating plate, and the surface of this heat slug 10 is not coated with resin but exposed.

By the way, in the present embodiment, the heat slug 10 is used only for heat radiation, therefore there is no need to apply electric potential. Accordingly, it should not always be a conductive material, but a pure ceramic not having a wiring layer may be employed. As a matter of course, a metal may be employed too.

According to the structure mentioned above, it is possible to further increase heat radiating effects, and the present embodiment may be employed preferably to the semiconductor chip 1 having large heat generating amount.

[Fourteenth Embodiment]

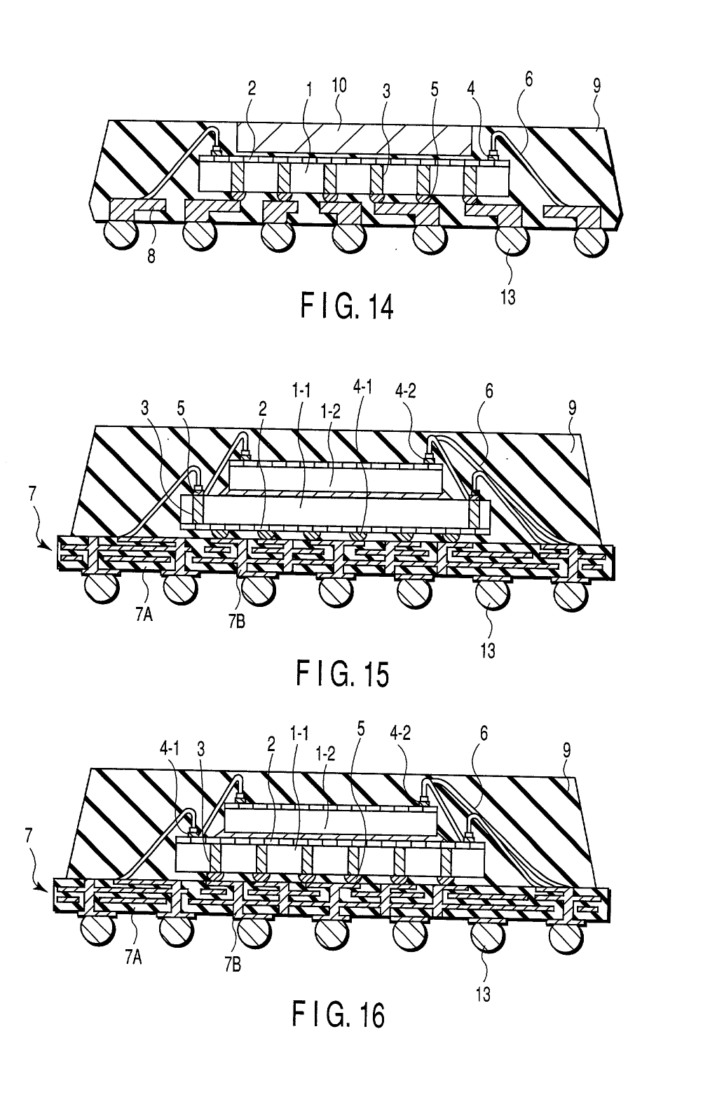

FIG. 14 is an outline cross sectional view for explaining a semiconductor device according to a fourteenth embodiment of the present invention, and is a modification of the semiconductor device according to the above fourth embodiment. In this fourteenth embodiment, as same in the above twelfth embodiment, a heat radiating plate is arranged on a semiconductor chip 1 of a package 9. A heat slug 10 is employed as a heat radiating plate, and the surface of this heat slug is not coated with resin but exposed.

In the present embodiment, the heat slug 10 is used only for heat radiation, therefore there is no need to apply electric potential. Accordingly, it should not always be a conductive material, but a pure ceramic not having a wiring layer may be employed. As a matter of course, a metal may be employed too.

According to the structure mentioned above, it is possible to further increase heat radiating effects, and the present embodiment may be employed preferably to the semiconductor chip 1 having large heat generating amount.

[Fifteenth Embodiment]

FIG. 15 is a cross sectional view for explaining a semiconductor device according to a fifteenth embodiment of the present invention, and is a modification of the semiconductor device according to the first embodiment. In this embodiment, two semiconductor chips are stacked. In the fifteenth embodiment, when the semiconductor chip 1 in the first embodiment is referred to as a semiconductor chip 1-1, then a second semiconductor chip 1-2 is stacked onto this semiconductor chip 1-1. In the fifteenth embodiment, a bonding wire 6 is employed for connection from connecting terminals 4-2 of the upper side semiconductor chip 1-2.

In the fifteenth embodiment mentioned above, the lower side semiconductor chip 1-1 has connecting terminals 4-1 distributed and arranged on the entire chip, and an element sensitive to voltage drop inside the chip is arranged on the lower surface thereof facing the printed circuit board, the performance of a semiconductor device is enhanced.

In the fifteenth embodiment mentioned above, the explanation is made with case wherein both of the semiconductor chips 1-1 and 1-2 are directly connected to the wiring substrate 7, and the semiconductor chips 1-1 and 1-2 are also connected with each other. However, the connection is not limited to this scheme. For example, it is possible that the semiconductor chip 1-1 is not directly connected to the semiconductor chip 1-2. Furthermore, the number of semiconductor chips to be stacked is not limited only to two in the present embodiment, and three or more may be employed. Further, in the present embodiment, a normal semiconductor chip not having the through hole 3 is employed as the upper side semiconductor chip 1-2, however, in the place of this, a semiconductor chip similar to the lower side semiconductor chip 1-1, i.e., a semiconductor having the through hole 3 wherein a conductive member is buried, may be employed.

[Sixteenth Embodiment]

FIG. 16 is a cross sectional views for explaining a semiconductor device according to sixteenth embodiment of the present invention, and is a modification of the semiconductor device according to the second embodiment. In this embodiment, two semiconductor chips are stacked. In the sixteenth embodiment, when the semiconductor chip 1 in the second embodiment is referred to as a semiconductor chip 1-1, then a second semiconductor chip 1-2 is stacked onto this semiconductor chip 1-1. In the sixteenth embodiment, a bonding wire 6 is employed for connection from connecting terminals 4-2 of the upper side semiconductor chip 1-2.

In the sixteenth embodiment mentioned above, the lower side semiconductor chip 1-1 has connecting terminals 5 distributed and arranged on the entire chip, and an element sensitive to voltage drop inside the chip is arranged on the upper surface thereof, and thus the performance of a semiconductor device is enhanced.

In the sixteenth embodiment mentioned above, the explanation is made with case wherein the both of the semiconductor chips 1-1 and 1-2 are directly connected to the wiring substrate 7, and the semiconductor chips 1-1 and 1-2 are also connected with each other. However, the connection is not limited to this scheme. For example, it is possible that the semiconductor chip 1-1 is not directly connected to the semiconductor chip 1-2. Furthermore, the number of semiconductor chips to be stacked is not limited only to two in the present embodiment, and three or more may be employed. Further, in the present embodiment, a normal semiconductor chip not having the through hole 3 is employed as the upper side semiconductor chip 1-2, however, in the place of this, a semiconductor chip similar to the lower side semiconductor chip 1-1, i.e., a semiconductor having the through hole 3 wherein a conductive member is buried, may be employed.

[Seventeenth Embodiment]

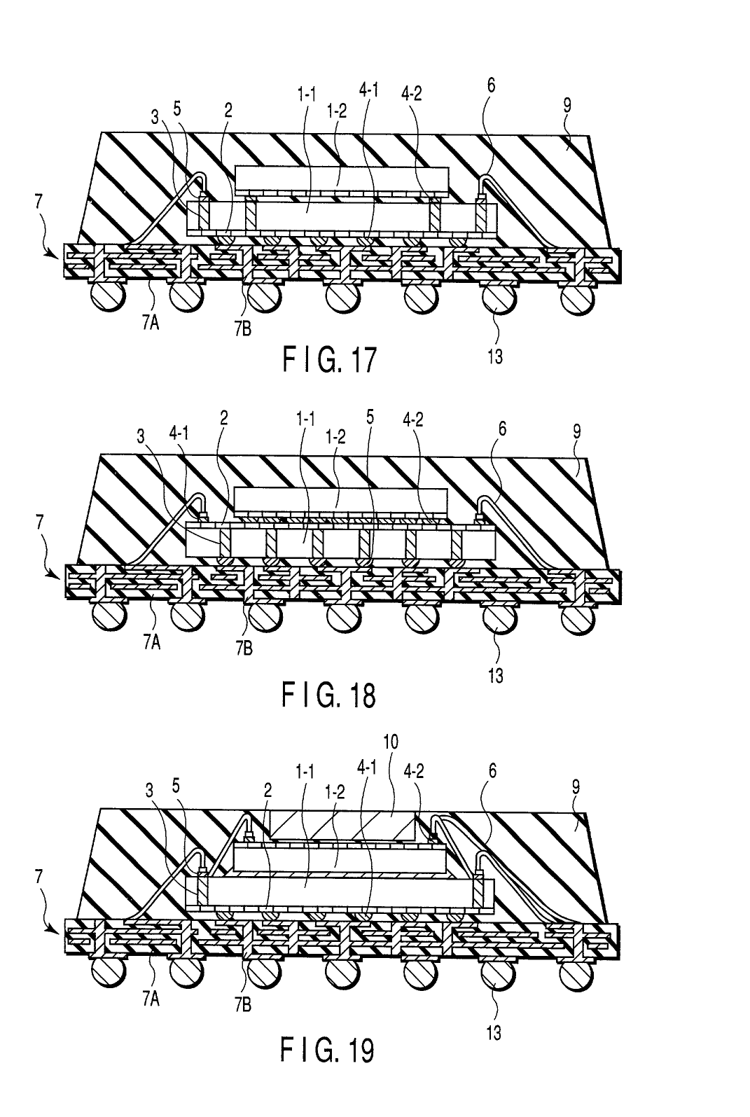

FIG. 17 is a cross sectional view for explaining a semiconductor device according to a seventeenth embodiment of the present invention, and is a modification of the semiconductor device according to the first embodiment. In this embodiment, two semiconductor chips are stacked. In the seventeenth embodiment, when the semiconductor chip 1 in the first embodiment is referred to as a semiconductor chip 1-1, then a second semiconductor chip 1-2 is stacked onto this semiconductor chip 1-1. In the seventeenth embodiment, conductive bumps are employed as connecting terminals 4-2 for connection from the upper side semiconductor chip 1-2.

In the seventeenth embodiment mentioned above, the lower side semiconductor chip 1-1 has connecting terminals 4-1 distributed and arranged on the entire chip, and an element sensitive to voltage drop inside the chip is arranged on the lower surface thereof facing the printed circuit board, the performance of a semiconductor device is enhanced.

In addition, in the seventeenth embodiment, it is also possible to supply power source electric potential or ground electric potential to the upper side chip 1-2 through the conductive member in the through hole 3 of the chip 1-1, as a consequence, it is possible to realize a semiconductor having higher performance.

In the seventeenth embodiment mentioned above, the explanation is made with case wherein only the semiconductor chip 1-1 is directly connected to the wiring substrate 7, and the semiconductor chips 1-1 and 1-2 are connected with each other. However, the connection is not limited to this scheme. For example, it is possible that the semiconductor chip 1-2 is directly connected to the wiring substrate 7 through the terminal 4-2, the through hole 3 of the chip 1-1, and the terminal 4-1. Furthermore, the number of semiconductor chips to be stacked is not limited only to two in the present embodiment, and three or more may be employed. Further, in the present embodiment, a normal semiconductor chip not having the through hole 3 is employed as the upper side semiconductor chip 1-2, however, in the place of this, a semiconductor chip similar to the lower side semiconductor chip 1-1, i.e., a semiconductor having the through hole 3 wherein a conductive member is buried, may be employed.

[Eighteenth Embodiment]

FIG. 18 is a cross sectional view for explaining a semiconductor device according to an eighteenth embodiment of the present invention, and is a modification of the semiconductor device according to the second embodiment. In this embodiment, two semiconductor chips are stacked. In the eighteenth embodiment, when the semiconductor chip 1 in the second embodiment is referred to as a semiconductor chip 1-1, then a second semiconductor chip 1-2 is stacked onto this semiconductor chip 1-1. In the eighteenth embodiment, conductive bumps are employed as connecting terminals 4-2 for connection from the upper side semiconductor chip 1-2.

In the eighteenth embodiment mentioned above, the lower side semiconductor chip 1-1 has connecting terminals 5 distributed and arranged on the entire chip, and an element sensitive to voltage drop inside the chip is arranged on the upper surface thereof, and thus the performance of a semiconductor device is enhanced.

In addition, in the eighteenth embodiment, it is also possible to supply power source electric potential or ground electric potential to the upper side chip 1-2 through the conductive member in the through hole 3 of the chip 1-1, as a consequence, it is possible to realize a semiconductor having higher performance.

In the eighteenth embodiment mentioned above, the explanation is made with case wherein only the semiconductor chip 1-1 is directly connected to the wiring substrate 7, and the semiconductor chips 1-1 and 1-2 are connected with each other. However, the connection is not limited to this scheme. For example, it is possible that the semiconductor chip 1-2 is directly connected to the wiring substrate 7 through the terminal 4-2, the through hole 3 of the chip 1-1, and the terminal 5. Furthermore, the number of semiconductor chips to be stacked is not limited only to two in the present embodiment, and three or more may be employed. Further, in the present embodiment, a normal semiconductor chip not having the through hole 3 is employed as the upper side semiconductor chip 1-2, however, in the place of this, a semiconductor chip similar to the lower side semiconductor chip 1-1, i.e., a semiconductor having the through hole 3 wherein a conductive member is buried, may be employed.

[Nineteenth Embodiment]

FIG. 19 is a cross sectional view for explaining a semiconductor device as a nineteenth embodiment according to the present invention. In the nineteenth embodiment, a heat radiating plate is arranged onto a semiconductor chip 1-2 of a package 9 so as to increase the heat radiating effects of the semiconductor device according to the fifteenth embodiment. In this embodiment, a heat slug 10 is employed as the heat radiating plate, and the surface of this heat slug 10 is not coated with resin but exposed. In the present embodiment, the heat slug 10 is used only for heat radiation, therefore there is no need to apply electric potential. Accordingly, it should not always be a conductive material, but a pure ceramic not having a wiring layer may be employed. As a matter of course, a metal may be employed too.

According to the structure mentioned above, it is possible to further enhance heat radiating effects even when both the semiconductor chips 1-1 and 1-2 make large heat generation.

In the nineteenth embodiment, an explanation is made with an example where the heat slug 10 is arranged in order to enhance the heat radiating effects of the semiconductors device according to the fifteenth embodiment, however, a similar structure may be applied also to the seventeenth embodiment shown in FIG. 17, which will be understood by those skilled in the art.

[Twentieth Embodiment]

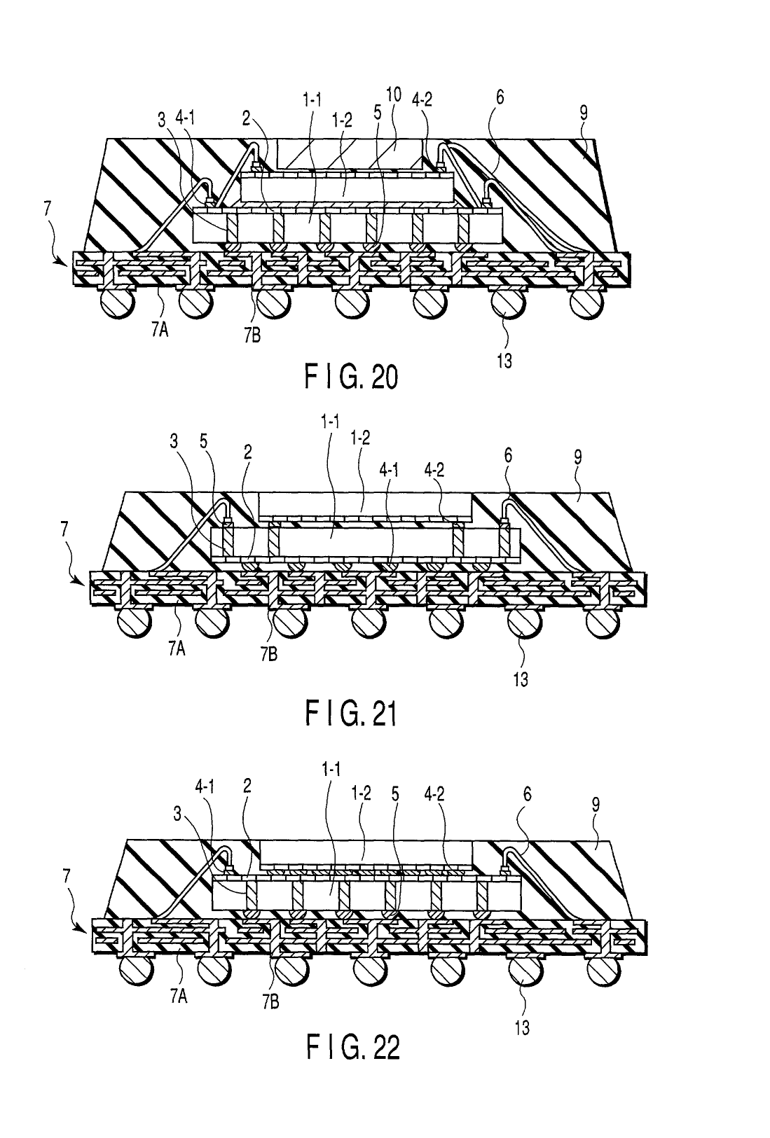

FIG. 20 is a cross sectional view for explaining a semiconductor device as a twentieth embodiment according to the present invention. In the twentieth embodiment, a heat radiating plate is arranged onto a semiconductor chip 1-2 of a package 9 so as to increase the heat radiating effects of the semiconductor device according to the sixteenth embodiment. In this embodiment, a heat slug 10 is employed as the heat radiating plate, and the surface of this heat slug 10 is not coated with resin but exposed. In the present embodiment, the heat slug 10 is used only for heat radiation, therefore there is no need to apply electric potential. Accordingly, it should not always be a conductive material, but a pure ceramic not having a wiring layer may be employed. As a matter of course, a metal may be employed too.

According to the structure mentioned above, it is possible to further enhance heat radiating effects even when both the semiconductor chips 1-1 and 1-2 make large heat generation.

In the twentieth embodiment, an explanation is made with an example where the heat slug 10 is arranged in order to enhance the heat radiating effects of the semiconductors devices according to the sixteenth embodiment, however, a similar structure may be applied also to the eighteenth embodiment shown in FIG. 18, which will be understood by those skilled in the art.

[Twenty First Embodiment]

FIG. 21 is a cross sectional view for explaining a semiconductor device as a twenty first embodiment according to the present invention. In the twenty first embodiment, a semiconductor chip 1-2 is exposed on the upper surface of a package 9 so as to increase the heat radiating effects of the semiconductor device according to the seventeenth embodiment.

Even in such structure, it is possible to increase heat radiating effects even when both the semiconductor chips 1-1 and 1-2 make large heat generation.

[Twenty Second Embodiments]

FIG. 22 is a cross sectional view for explaining semiconductor device as a twenty second embodiment according to the present invention. In the twenty second embodiment, a semiconductor chip 1-2 is exposed on the upper surface of a package 9 so as to increase the heat radiating effects of the semiconductor device according to the eighteenth embodiment.

Even in such structure, it is possible to increase heat radiating effects even when both the semiconductor chips 1-1 and 1-2 make large heat generation.

[Twenty Third Embodiment]

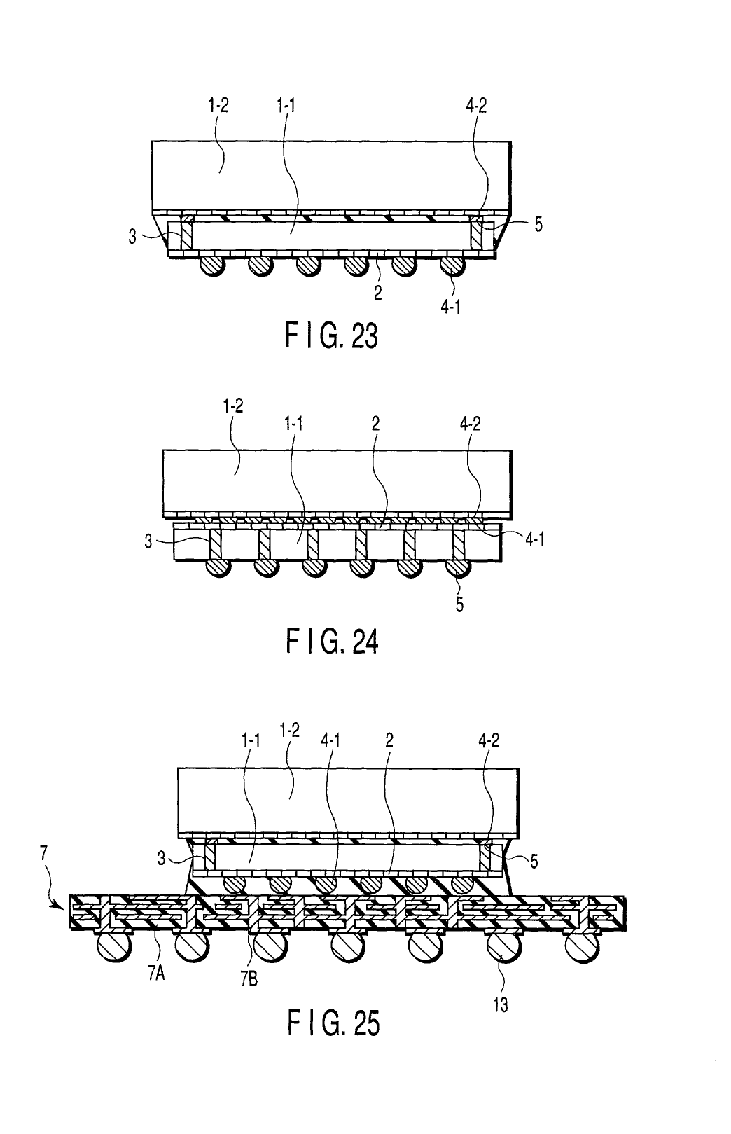

FIG. 23 is a cross sectional view for explaining semiconductor device as a twenty third embodiment according to the present invention. In the twenty third embodiment, two semiconductor chips 1-1 and 1-2 are face-to-face connected through conductive bump 4-2 and through holes 3. The space between the semiconductor chips 1-1 and 1-2 is reinforced by filled resin.

The semiconductor chip 1-1 wherein a through hole 3 is formed is inevitably made thin for restriction of the depth of the through hole 3. Accordingly, in order to reinforce the insufficient strong of the semiconductor chip 1-1 having the through hole 3 concerned, it is preferable to design thick and large the semiconductor chip 1-2 that does not have a corresponding through hole.

By the way, in the embodiment, the connecting terminal 4-1 formed on the back surface side of the stacked surface between the semiconductor chip 1-1 and the semiconductor chip 1-2 is employed as an external connecting terminal with a mother board, thereby a Chip Scale Package (CSP) is configured. However, the connecting terminal may be connected to a wiring substrate for packaging or a lead frame, and thereby a package or a module may be formed.

[Twenty Fourth Embodiments]

FIG. 24 is a cross sectional view for explaining a semiconductor device as a twenty fourth embodiment according to the present invention. In the twenty fourth embodiment, two semiconductor chips 1-1 and 1-2 are face-to-face connected through a conductive bump 4-1. The space between the semiconductor chips 1-1 and 1-2 is reinforced by filled resin.

The semiconductor chip 1-1 wherein a through hole 3 is formed is inevitably made thin for restriction of the depth of the through hole 3. Accordingly, in order to reinforce the insufficient strong of the semiconductor chip 1-1 having the through hole 3 concerned, it is preferable to design thick and large the semiconductor chip 1-2 that does not have a corresponding through hole.

By the way, in these embodiments, the connecting terminal 5 formed on the back surface side of the stacked surface between the semiconductor chip 1-1 and the semiconductor chip 1-2 via a through hole 3 is employed as an external connecting terminal with a mother board, thereby a Chip Scale Package (CSP) is configured. However, the connecting terminal may be connected to a wiring substrate for packaging or a lead frame, and thereby a package or a module may be formed.

[Twenty Fifth Embodiment]

FIG. 25 is a cross sectional view for explaining a semiconductor device as a twenty fifth embodiment according to the present invention. In the twenty fifth embodiment, the semiconductor device according to the twenty third embodiment illustrated in the FIG. 23 is mounted on the wiring substrate 7, and sealing resin is filled in between the semiconductor chips 1-1 and 1-2 and between the semiconductor chip 1-1 and the wiring substrate 7, thereby a package or a module is formed. In FIG. 25, identical numerals are used to identical components in FIG. 23, and their detailed explanations are herein omitted.

According to the structures mentioned above, even in the case where both the semiconductor chips 1-1 and 1-2 are made thin, there is no problem of insufficient strength, and it is possible to make semiconductor devices convenient for handling.

By the way, in the twenty third embodiment, if the number of connecting terminals 4-1 formed on the back surface side of the stacked surface between the semiconductor chip 1-1 and the semiconductor chip 1-2 increases and causes high density, it would be difficult to route in a mother board. However, in the case of the present embodiment, it is possible to loosen the pitch of the external connecting terminal 13 by use of the wiring substrate 7, therefore, the present embodiment is effective in the case of a semiconductor device having many external connecting terminals.

[Twenty Sixth Embodiment]

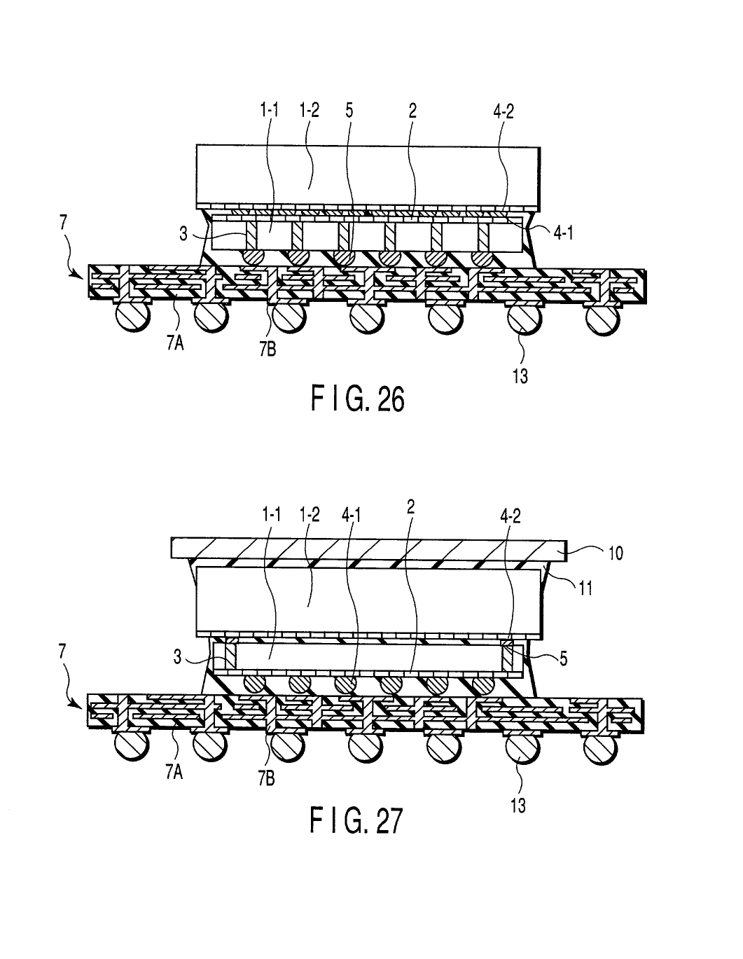

FIG. 26 is a cross sectional view for explaining a semiconductor device as a twenty sixth embodiment according to the present invention. In the twenty sixth embodiment, the semiconductor devices according to the twenty fourth embodiment illustrated in the FIG. 24 is mounted on the wiring substrate 7, and sealing resin is filled in between the semiconductor chips 1-1 and 1-2 and between the semiconductor chip 1-1 and the wiring substrate 7, thereby a package or a module is formed. In FIG. 26, identical numerals are used to identical components in FIGS. 23 and 24, and their detailed explanations are herein omitted.

According to the structures mentioned above, even in the case where both the semiconductor chips 1-1 and 1-2 are made thin, there is no problem of insufficient strength, and it is possible to make semiconductor devices convenient for handling.

By the way, in the twenty fourth embodiment, if the number of connecting terminals 5 formed on the back surface side of the stacked surface between the semiconductor chip 1-1 and the semiconductor chip 1-2 increases and causes high density, it would be difficult to route in a mother board. However, in the case of the present embodiment, it is possible to loosen the pitch of the external connecting terminal 13 by use of the wiring substrate 7, therefore, the present embodiment is effective in the case of a semiconductor device having many external connecting terminals.

[Twenty Seventh Embodiment]

FIG. 27 is a cross sectional view for explaining a semiconductor device as a twenty seventh embodiment according to the present invention. In the twenty seventh embodiment, a heat slug 10 is applied by use of a highly radiating resin 11 onto a semiconductor chip 1-2 in the semiconductor devices according to the twenty fifth embodiment illustrated in FIG. 25.

According to the structures mentioned above, it is possible to increase the heat radiating effects, and also to protect the semiconductor chip 1-2 by avoiding the exposure of the semiconductor chip 1-2.

[Twenty Eighth Embodiment]

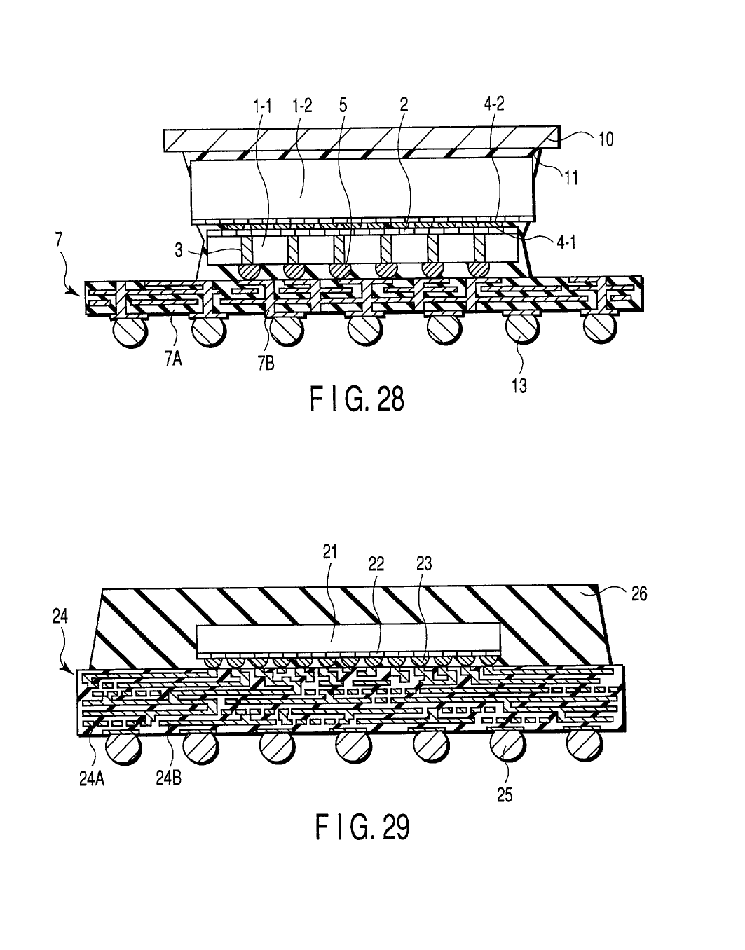

FIG. 28 is a cross sectional view for explaining a semiconductor device as a twenty eighth embodiment according to the present invention. In the twenty eighth embodiment, a heat slug 10 is applied by use of a highly radiating resin 11 onto a semiconductor chip 1-2 in the semiconductor devices according to the twenty sixth embodiment illustrated in FIG. 26.

According to the structures mentioned above, it is possible to increase the heat radiating effects, and also to protect the semiconductor chip 1-2 by avoiding the exposure of the semiconductor chip 1-2.

Heretofore, the present invention has been explained in detail with reference to the first to the twenty eighth embodiments. As this invention may be embodied in several forms without departing from the sprit of essential characteristics thereof, the present embodiment is therefore illustrative and not restrictive, since the scope of the invention is defined by the appended claims rather than by the description preceding them, and all changes that fall within meets and bounds of the claims, or equivalence of such as meets and bounds are therefore intended to embraced by the claims. Each of the above embodiments includes inventions at various stages, and by appropriate combination of a plurality of structural components disclosed herein, various inventions may be extracted.

As mentioned heretofore, according to the present invention, it is possible to obtain a semiconductor device where necessary functions are realized by the minimum costs.

Further, according to the present invention, it is possible to obtain a semiconductor device that can restrict voltage drop in the semiconductor chip inside thereof, even when the semiconductor chip size is enlarged and power source voltage becomes lower.

Still further, according to the present invention, it is possible to obtain a semiconductor device having a high performance and yet low cost packaging structure.

What is claimed is:

1. A semiconductor device comprising:
a first semiconductor chip where a semiconductor element is formed;
a first connecting terminal arranged on a semiconductor element formation surface side in the first semiconductor chip, and connected electrically to the semiconductor element;
a conductive member buried in a through hole that goes through the first semiconductor chip;
a second connecting terminal arranged on a back surface side of the semiconductor element formation surface in the first semiconductor chip, and connected electrically to the semiconductor element via the conductive member;
a wiring substrate to which the first semiconductor chip is mounted; and
a third connecting terminal at least portion of which is formed at a position corresponding to one of the first connecting terminal and the second connecting terminal, and which is electrically connected to the one of the first connecting terminal and the second connecting terminal.

2. A semiconductor device comprising:
a first semiconductor chip where a semiconductor element is formed;
a first connecting terminal arranged on a semiconductor element formation surface side in the first semiconductor chip, and connected electrically to the semiconductor element;
a conductive member buried in a through hole that goes through the first semiconductor chip;
a second connecting terminal arranged on a back surface side of the semiconductor element formation surface in the first semiconductor chip, and connected electrically to the semiconductor element via the conductive member;
a lead frame to which the first semiconductor chip is mounted, and at least part of which is arranged at a position facing to one of the first connecting terminal and the second connecting terminal, and which is electrically connected to the one connecting terminal; and
an insulator that seals an inner lead portion of the lead frame and the first semiconductor chip.

3. A semiconductor device comprising:
a first semiconductor chip where a semiconductor element is formed;
a plurality of first connecting terminals arranged on a semiconductor element formation surface side in the first semiconductor chip, and connected electrically to the semiconductor element;
conductive members buried in a plurality of through holes that go through the first semiconductor chip; and
a plurality of second connecting terminals arranged on a back surface side of the semiconductor element formation surface in the first semiconductor chip, and connected electrically to the semiconductor element via the conductive members;
wherein, at least either the first connecting terminals or the second connecting terminals is coupled to a assembly board.

4. A semiconductor device according to claim 3, wherein, one of the first connecting terminals and the second connecting terminals are arranged to be facing to the assembly board and the average density of arrangement of the one of the first connecting terminals and the second connecting terminals are made lower than that of another of the first connecting terminals and the second connecting terminals.

5. A semiconductor device according to claim 4, wherein, a portion of either the first connecting terminals or the second connecting terminals are distributed and arranged on the central area of the semiconductor chip, and power source supply potential or ground potential are to be applied thereto.

6. A semiconductor device according to claim 1, further comprising a bonding wire configured to connect at least portion of the connecting terminal that is not used for flip-chip connection with the wiring substrate of the first connecting terminal and the second connecting terminal in the first semiconductor chip with the third connecting terminal formed on the wiring substrate.

7. A semiconductor device according to claim 2, further comprising a bonding wire configured to connect at least portion of the connecting terminal that is not used for flip-chip connection with the lead frame of the first connecting terminal and the second connecting terminal in the first semiconductor chip with an inner lead portion of the lead frame.

8. A semiconductor device according to claim 1, further comprising a second semiconductor chip stacked on the first semiconductor chip, wherein at least portion of the connecting terminal that is not used for flip-chip connection with the wiring substrate of the first connecting terminal and the second connecting terminal in the first semiconductor chip is coupled to the second semiconductor chip.

9. A semiconductor device according to claim 1, further comprising a second to an n-th (wherein n is a positive integer of three or more) semiconductor chips stacked above the first semiconductor chip, wherein at least portion of the connecting terminal that is not used for flip-chip connection with the wiring substrate of the first connecting terminal and the second connecting terminal in the first semiconductor chip is coupled to the second to n-th semiconductor chips.

10. A semiconductor device according to claim 2, further comprising a second semiconductor chip stacked on the first semiconductor chip, wherein at least portion of the connecting terminal that is not used for flip-chip connection with the lead frame of the first connecting terminal and the second connecting terminal in the first semiconductor chip is coupled to the second semiconductor chip.

11. A semiconductor device according to claim 2, further comprising a second to an n-th (wherein n is a positive integer of three or more) semiconductor chips stacked above the first semiconductor chip, wherein at least portion of the connecting terminal that is not used for flip-chip connection with the lead frame of the first connecting terminal and the second connecting terminal in the first semiconductor chip is coupled to the second to n-th semiconductor chips.

12. A semiconductor device according to claim 3, further comprising a second semiconductor chip stacked on the first semiconductor chip, wherein at least portion of the connecting terminals arranged on a stacked surface between the first semiconductor chip and the second semiconductor chip of the first connecting terminals and the second connecting terminals in the first semiconductor chip is coupled to the second semiconductor chip.

13. A semiconductor device according to claim 3, further comprising a second to an n-th (wherein n is a positive integer of three or more) semiconductor chips stacked above first semiconductor chip, wherein at least portion of the connecting terminals arranged on a stacked surface between the first semiconductor chip and the second semiconductor chip of the first connecting terminals and the second connecting terminals in the first semiconductor chip is coupled to the second to n-th semiconductor chips.

14. A semiconductor device according to claim 8, further comprising a bonding wire configured to connect at least portion of the plurality of connecting terminals of the semiconductor chips to be stacked with each other.

15. A semiconductor device according to claim 10, further comprising a bonding wire configured to connect at least portion of the plurality of connecting terminals of the semiconductor chips to be stacked with each other.

16. A semiconductor device according to claim 12, further comprising a bonding wire configured to connect at least portion of the plurality of connecting terminals of the semiconductor chips to be stacked with each other.

17. A semiconductor device according to claim 8, further comprising a conductive bump configured to connect at least portion of the plurality of connecting terminals of the semiconductor chips to be stacked with each other.

18. A semiconductor device according to claim 10, further comprising a conductive bump configured to connect at least portion of the plurality of connecting terminals of the semiconductor chips to be stacked with each other.

19. A semiconductor device according to claim 12, further comprising a conductive bump configured to connect at least portion of the plurality of connecting terminals of the semiconductor chips to be stacked with each other.

20. A semiconductor device comprising:
a first semiconductor chip where a semiconductor element is formed;
a first connecting terminal arranged on a semiconductor element formation surface side in the first semiconductor chip, and connected electrically to the semiconductor element;
a conductive member buried in a through hole that goes through the first semiconductor chip;
a second connecting terminal arranged on a back surface side of the semiconductor element formation surface in the first semiconductor chip, and connected electrically to the semiconductor element via the conductive member;
a second semiconductor chip stacked on the first semiconductor chip;
a third connecting terminal arranged on a semiconductor element formation surface side in the second semiconductor chip;
wherein, one of the first connecting terminal and the second connecting terminal of the first semiconductor chip is arranged at a position facing to the third connecting terminal of the second semiconductor chip, the first semiconductor chip and the second semiconductor chip are electrically connected with each other through the facing connecting terminals, and
the second semiconductor chip is thicker or larger than the first semiconductor chip.
